(19) United States
(12) Patent Application Publication
(10) Pub. No.: US 2017/0145724 A1
(43) Pub. Date: May 25, 2017

(54) HINGED DEVICE

(71) Applicant: Microsoft Technology Licensing, LLC, Redmond, WA (US)

(72) Inventor: Kabir SIDDIQUI, Sammamish, WA (US)

(73) Assignee: MICROSOFT TECHNOLOGY LICENSING, LLC, Redmond, WA (US)

(21) Appl. No.: 14/947,994

(22) Filed: Nov. 20, 2015

(51) Int. Cl. E05F 1/12; G06F 1/16; E05D 3/12; H05K 1/03; E05D 11/00; E05F 3/20

(52) U.S. Cl. CPC E05F 1/1284; E05D 11/0081; E05F 3/20; E05D 3/12; H05K 1/0393; G06F 1/1641

(57) ABSTRACT

The description relates to devices, such as computing devices that have hinged portions. One example can include a first portion and a second portion. This example can also include a hinge assembly that can rotatably secure the first portion to the second portion with a flexible hinge that is biased into the second portion such that a length of the flexible hinge exposed between the first and second portions changes as the first and second portions are rotated through a range of angular orientations.

### BRIEF DESCRIPTION OF THE DRAWINGS

The accompanying drawings illustrate implementations of the concepts conveyed in the present document. Features of the illustrated implementations can be more readily understood by reference to the following description taken in conjunction with the accompanying drawings. Like reference numbers in the various drawings are used wherever feasible to indicate like elements. Further, the left-most numeral of each reference number conveys the FIG. and associated discussion where the reference number is first introduced.

FIGS. 1-2, 4, and 9-11 show perspective views of example devices in accordance with some implementations of the present concepts.

FIGS. 3 and 5 show perspective views of hinge assembly examples in accordance with some implementations of the present concepts.

FIGS. 6-8 show sectional views of hinge assembly examples in accordance with some implementations of the present concepts.

### DESCRIPTION

The present concepts relate to devices, such as computing devices, employing flexible hinges that rotationally secure device portions. The flexible hinges can be biased to affect a length of the flexible hinge that is interposed between the device portions at various angular orientations.

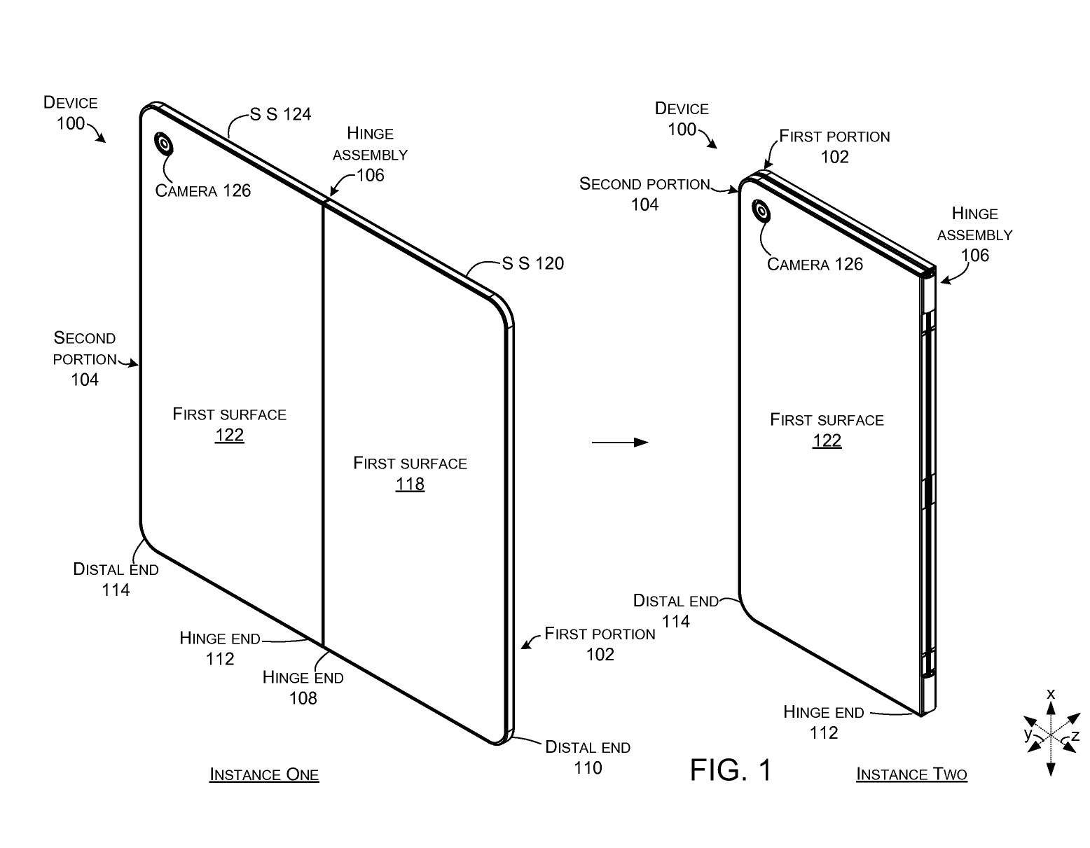

Introductory FIG. 1 shows an example device 100. In this example, the device 100 has first and second portions 102 and 104 that are rotatably secured together by a hinge assembly 106. The first portion 102 can extend from a hinge end 108 to a distal end 110. The second portion 104 can extend from a hinge end 112 to a distal end 114. The first portion can include opposing first and second major surfaces 118 and 120 (hereinafter, first and second surfaces). Similarly, the second portion can include opposing first and second major surfaces 122 and 124 (hereinafter, first and second surfaces). In this example, a camera 126 is exposed in first surface 122 of the second portion 104.

The first surfaces 118 and 122 and the second surfaces 120 and 124 can be manifest in various configurations. For instance, in this example, the first surfaces can be manifest as protective surfaces (e.g., manifest from materials that protect underlying components). The second surfaces can be manifest as displays upon which graphical user interfaces (GUIs) can be presented. In another example, both the first and second surfaces can be manifest as displays or neither the first nor the second surfaces can be displays, among other examples.

Instance One shows first portion 102 and second portion 104 oriented at 180 degrees from one another in what can be termed a ‘fully open orientation.’ In this orientation the first portion 102 and the second portion 104 are adjacent and coplanar. Thus, in example implementations where the second surfaces are manifest as displays, in the fully open orientation these displays can be addressed (e.g., treated) as a single display with larger (e.g. 2×) dimensions.

Instance Two shows device 100 in a closed orientation. The closed orientation can be viewed as defining a near zero degree angle between the first and second portions 102 and 104 as measured relative to the hinge assembly 106. In this case, the first portion is rotated counter-clockwise so that the second surfaces 120 and 124 are positioned inwardly (e.g., facing one another) against one another. The first surfaces 118 and 122 are outwardly facing. In this configuration, the first surfaces can protect the second surfaces in the closed configuration.

This example implementation can alternatively or additionally allow the first portion 102 to be rotated clockwise until the first surfaces 118 and 122 are inwardly facing and positioned against one another and the second surfaces 120 and 124 are outwardly facing. This orientation can also be termed a closed configuration and for purposes of clarification can be referred to as a 360 degree orientation.

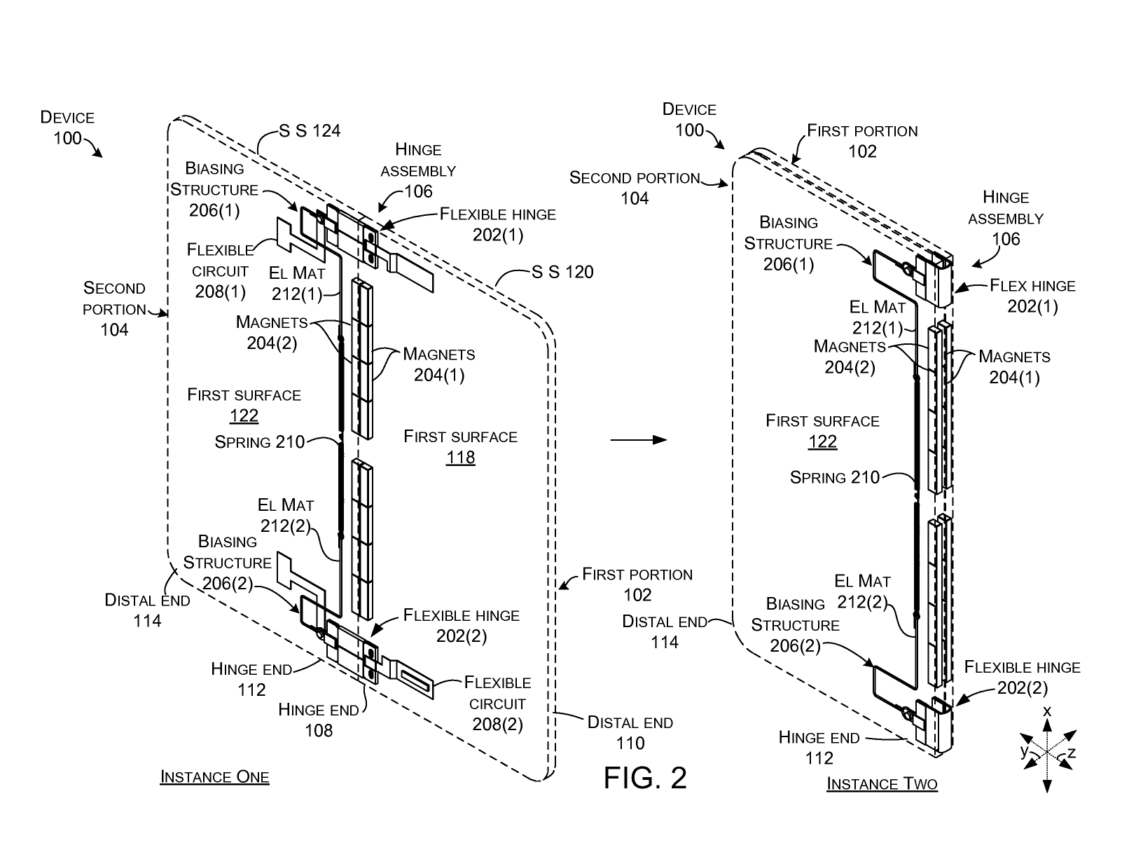

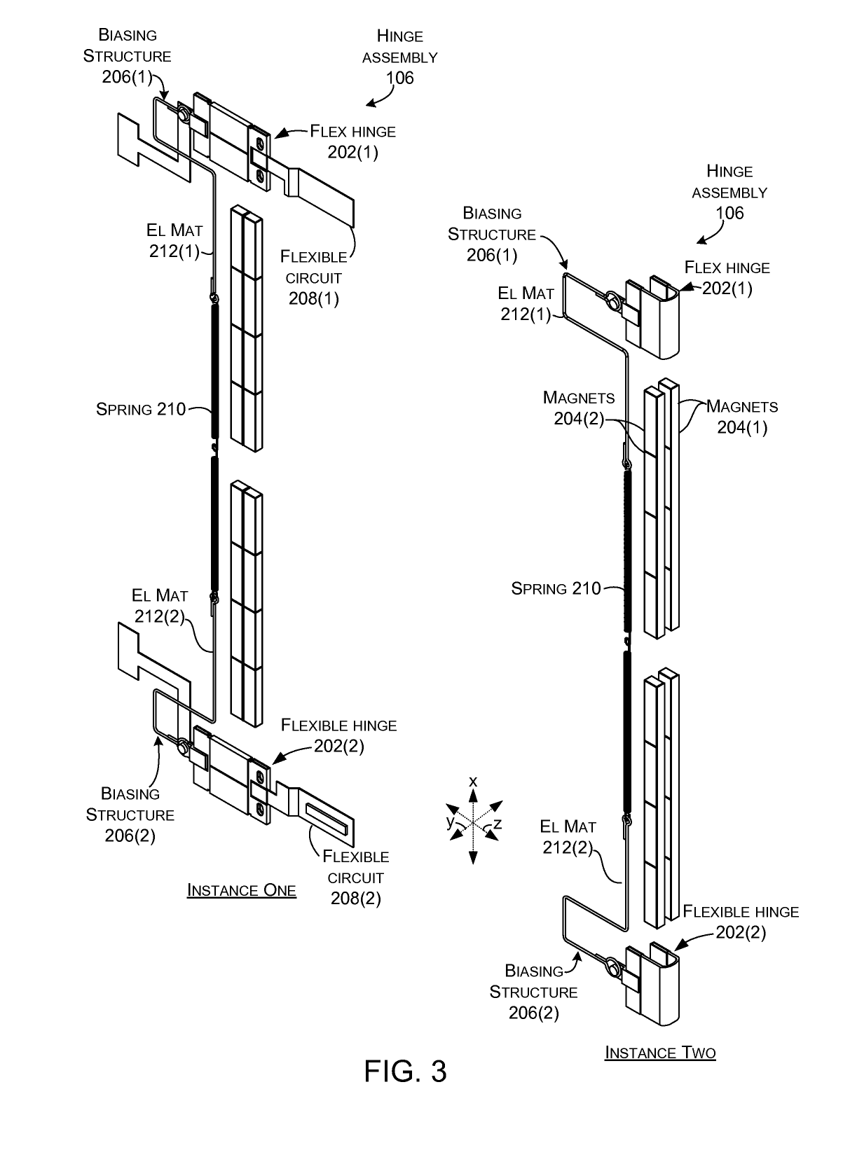

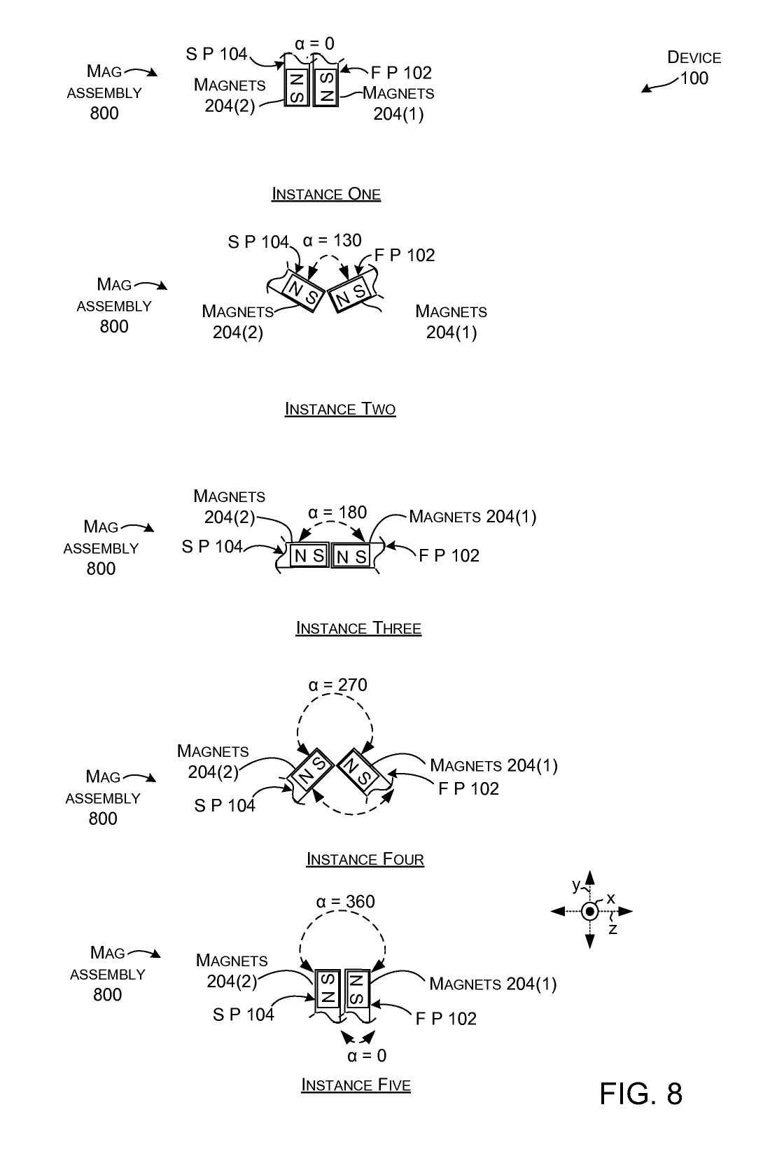

FIG. 2 is similar to FIG. 1 except the first and second portions 102 and 104 of device 100 are shown in ghost to allow some underlying components of the hinge assembly 106 to be visualized. FIG. 3 shows the hinge assembly 106 in isolation. Thus, FIGS. 2-3 collectively show details of hinge assembly 106. In this case, hinge assembly 106 includes upper and lower flexible hinges 202(1) and 202(2) and magnets 204. Magnets 204(1) are positioned in first portion 102 and magnets 204(2) are positioned in second portion 104. Note that not all of these magnets are designated with specificity. Briefly, magnets 204(1) and 204(2) can create forces to bias the first and second portions to specific orientations, such as zero degrees, 180 degrees, and/or 360 degrees, among others. The function of these magnets is explained below relative to FIG. 8.

Flexible hinges 202(1) and 202(2) can also be associated with a biasing structure 206(1) and 206(2) and a flexible circuit 208(1) and 208(2) (shown in Instance One, removed in Instance Two). The flexible circuit 208 can be configured to electrically couple components of the first portion 102 to components of the second portion 104.

Biasing structures 206(1) and 206(2) can bias the flexible hinges 202 into the second portion 104 such that a length of the flexible hinge in the second portion changes as the first and second portions are rotated through a range of angles. Stated another way, the biasing structure can exert a force on the flexible hinge into the second portion. This force can be overcome to varying degrees at various orientations of the first and second portions so that a length of the flexible hinge interposed between the first and second portions is different at different orientations.

In this case, the biasing structures 206 share a common spring 210. In this case, the spring 210 is positioned between the two biasing structures 206(1) and 206(2). Opposing ends of the spring are indirectly connected to the biasing structures via first and second intervening elongate material 212(1) and 212(2). Stated another way, a first end of the spring is connected to the first elongate material 212(1), and an opposite end of the first elongate material is connected to the flexible hinge 202(1). Similarly, the second end of the spring is connected to the second elongate material 212(2), and an opposite end of the second elongate material is connected to flexible hinge 202(2). The elongate material can be manifest as various materials, such as a metal wire, metal cable, and/or polymer fiber, among others.

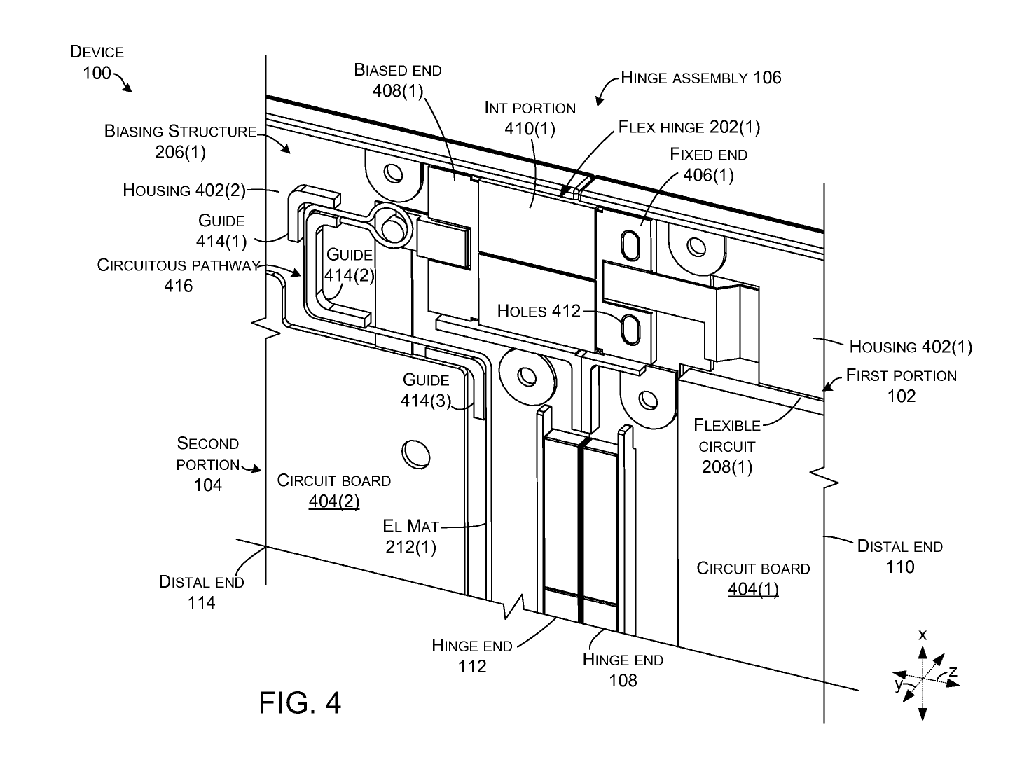

FIG. 4 shows a portion of device 100 relating to hinge assembly 106 and specifically to flexible hinge 202(1) and biasing structure 206(1). The device 100 is in the fully open position with first portion 102 and second portion 104 abutting one another and coplanar. For purposes of explanation, the first surfaces 118 and 122 are removed (compare to Instance One of FIGS. 1 and 2). Second surface 120 can be manifest as or positioned on a housing 402(1) and second surface 124 can be manifest as or positioned on a housing 402(2). Various components, such as circuit boards 404(1) and 404(2) can be positioned on the housings.

In this case, the flexible hinge 202(1) includes a fixed end 406(1), an opposing biased end 408(1), and an intervening portion 410(1). In other implementations, both ends could be biased. The fixed end 406(1) can be secured to housing 402(1) by fasteners (not shown) via holes 412. The biased end 408(1) can be slideably retained between housing 402(2) and the second portion 104's second surface (removed). The biased end 408(1) can be resiliently biased by biasing structure 206(1). Recall that the biasing structure's elongate material 212(1) extends from the biasing portion to spring 210 (FIG. 3). In this implementation, multiple guides 414 can be secured to housing 402(2). The guides 414 can define a circuitous pathway (indicated generally at 416) for the elongate material between the spring (210, FIG. 3) and the biasing end 408(1). This configuration can allow the (common or shared) spring 210 (FIG. 3) to be positioned proximate to the hinge ends 108 and 112 of the first and second portions 102 and 104 rather than the distal ends 110 and 114. Further, this configuration can reduce an amount of area occupied by the biasing structure 206(1) above (e.g., in the positive x-reference direction) the circuit board 404(2) so that this region can be dedicated to an antenna (not shown) in some implementations.

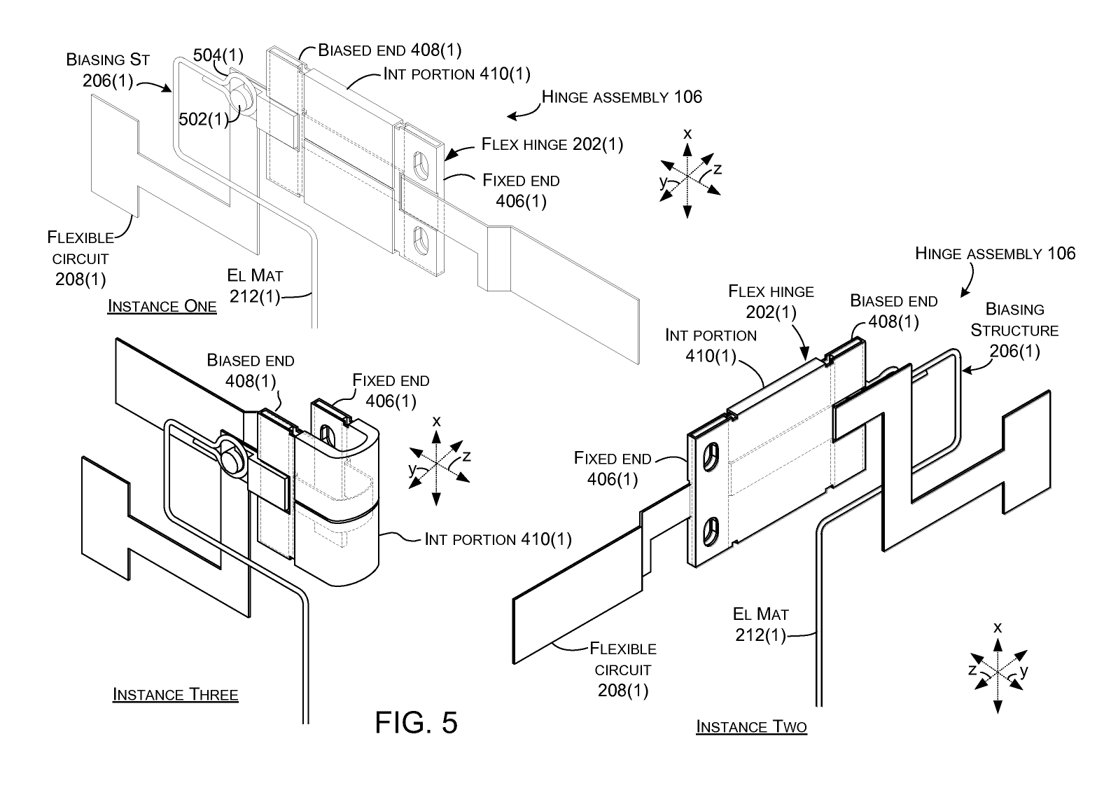

FIG. 5 shows an enlarged view of flexible hinge 202(1) of hinge assembly 106. In this case, flexible hinge 202(1) includes a post 502. A loop 504 on the elongate material 212(1) serves to connect the flexible hinge and the elongate material. Other connection mechanisms can be employed. When positioned within the second portion 104, the post 502 can contact the first surface 122 and thus, the loop is retained on the post.

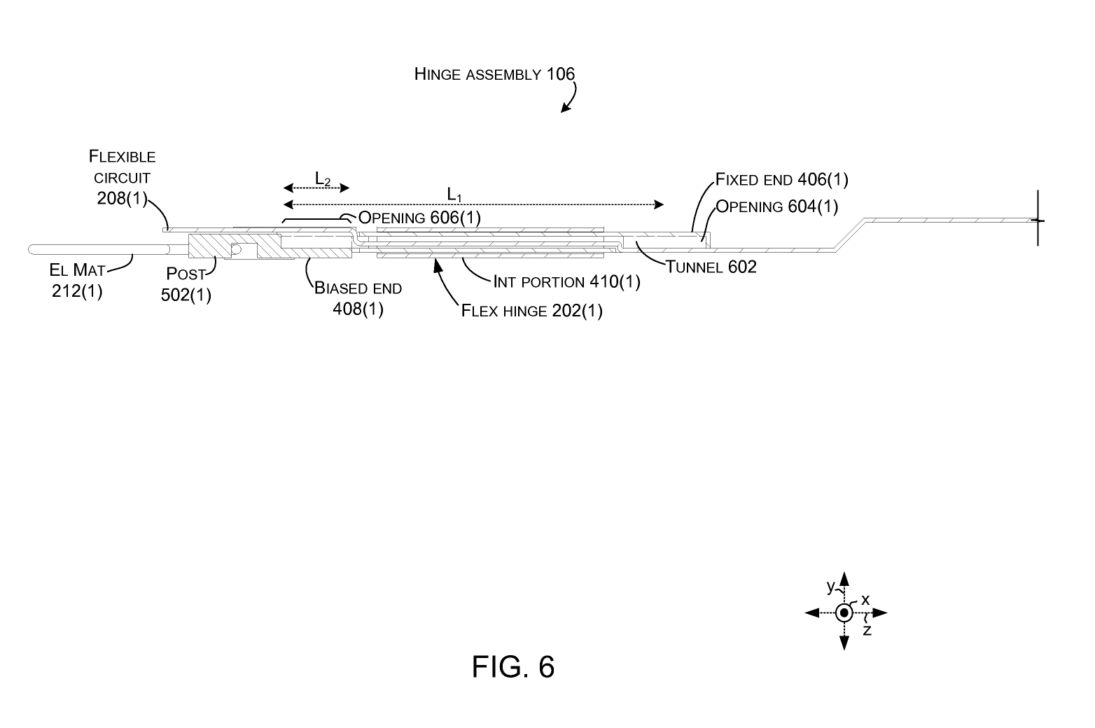

FIG. 5 also shows how the flexible hinge 202(1) can protect the flexible circuit 208(1). This protection can be mechanical protection and/or electronic protection. Instance One and Instance Two show the flexible circuit 208(1) in the fully open orientation. Instance Three shows the flexible circuit 208(1) in the closed orientation. Note that in the closed orientation (and/or partially open orientation) the intervening portion 410(1) can be exposed to the environment. For example, compare Instance One and Instance Two of FIG. 2, which are analogous to Instance One and Instance Three of FIG. 5. As illustrated in FIG. 5, the intervening portion of the flexible hinge mechanically protects the flexible circuit. In this case, the flexible circuit is contained within the intervening portion. In this implementation, the flexible circuit can be contained in the intervening portion because the intervening portion is hollow (e.g., defines a tunnel (shown on FIG. 6) and the flexible circuit can pass through this tunnel between the fixed end 406(1) and the biased end 408(1). Thus, the flexible circuit is physically protected from being contacted by items in the environment. Further, some implementations of the flexible hinge can offer electronic protection to the flexible circuit. For example, the flexible hinge can provide a Faraday cage (or a portion of a Faraday cage in combination with other components) that protects the flexible circuit from radio frequency interference. For instance, the flexible hinge can be manifest as a metal mesh that is overlaid with a polymer or other material (e.g., a polymer coated mesh). The metal mesh can provide a Faraday cage around the flexible circuit in the tunnel.

FIG. 6 shows a sectional view of flexible hinge 202(1) along the yz-reference plane. The flexible hinge can define tunnel 602 that passes at least along a part of the length between the fixed end 406(1) and the biased end 408(1) (e.g., through the intervening portion 410(1)). In this case the tunnel has a length L₁ in the z reference direction. The flexible circuit 208(1) can enter the tunnel at openings 604(1) and 606(1). Note that in this case, opening 606(1) is elongate to allow movement of the flexible hinge 202(1) in the z direction independent of (e.g., without pulling on) the flexible circuit. Thus, stress forces that may be imparted on the flexible hinge during rotation of the first and second portions 102 and 104 are not transferred to the flexible circuit. Stated another way, a length L₂ of opening 606(1) can be approximately equal to an extent that the flexible hinge 202(1) can be biased into the second portion by the biasing structure 206(1) during rotation of the first and second portions.

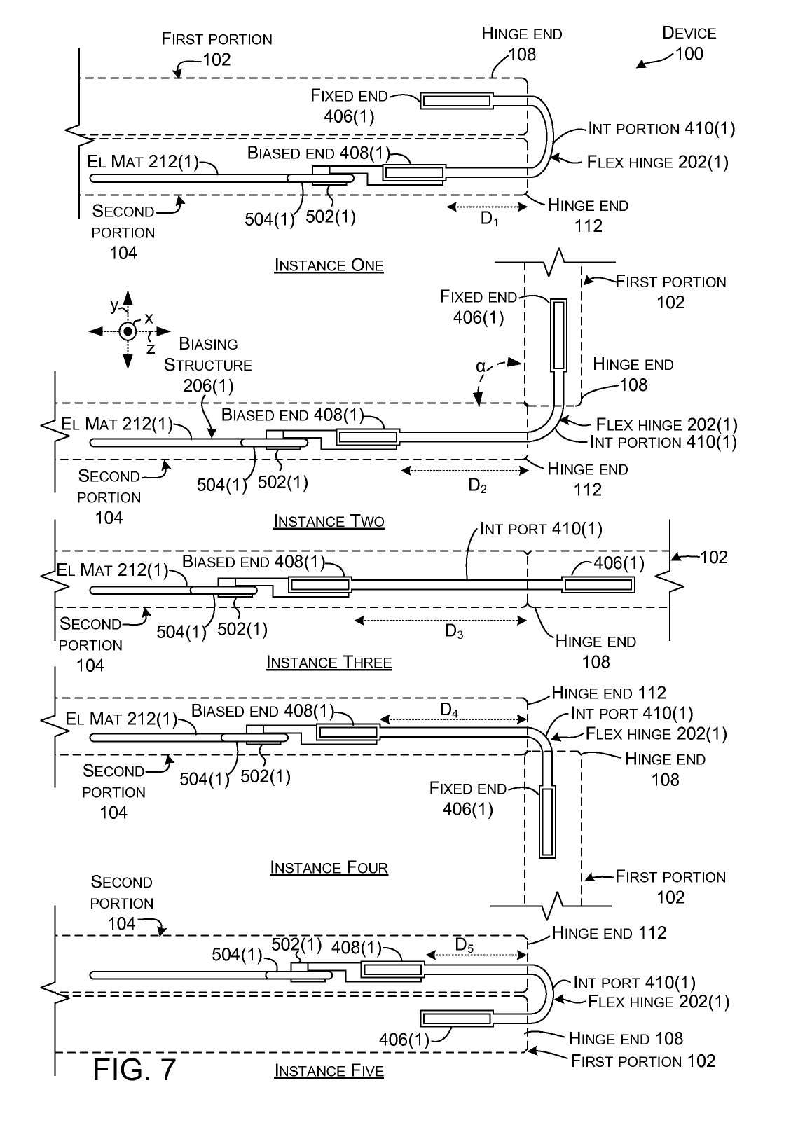

Looking collectively at FIGS. 5 and 6, from one perspective, the flexible hinge 202(1) can be at least partially co-extensive with the flexible circuit 208(1). The flexible hinge can be resiliently biased to pull a region (e.g., some of the intervening portion 410(1)) of the flexible hinge into at least one of the first and second portions 102 and 104 when the first and second portions are coplanar in a fully open configuration. The resilient bias can be overcome to withdraw the region when the first and second portions are folded over one another in a closed configuration. This aspect is illustrated and discussed more relative to FIG. 7.

FIG. 7 shows how the biasing structure 206(1) can bias the flexible hinge 202(1) into the second portion 104. This bias pulls more of the flexible hinge into the second portion in open positions and is greater at the fully open (e.g., 180 degree) position. The bias is overcome as rotation approaches the closed positions (e.g., 0 degrees and 360 degrees).

Instance One shows the first portion 102 folded over and against the second portion 104 (e.g., closed or zero degree orientation). Part of the intervening portion 410(1) of the flexible hinge 202(1) is exposed and another part (represented by length or distance D₁) is contained in the second portion 104.

Instance Two shows the first portion 102 rotated until the angular orientation a relative to the second portion 104 is about 90 degrees. At this point more of the intervening portion 410(1) has been biased into the second portion 104 by the biasing structure 206(1), thus distance D₂ is greater than D₁.

Instance Three shows the first portion 102 rotated until it is coplanar with the second portion 104 (e.g., fully open or 180 degree orientation). Further, more of the intervening portion 410(1) is biased into the second portion so that the first and second portions can move toward and abut one another. This is evidenced in that distance D₃ is greater than distance D₂.

Instance Four shows first portion 102 rotated about another 90 degrees (e.g., to about 270 degrees relative to the second portion 104). This creates a force that pulls more of the intervening portion 410(1) out of the second portion 104 so that distance D₄ is less than distance D₃.

Instance Five shows the first portion 102 completing its rotation relative to the second portion 104 to create a 360 degree orientation. At this point, more of the intervening portion 410(1) is exposed than in Instance Four (e.g., distance D₅ is less than D₄).

From one perspective, biasing structure 206(1) can bias the flexible hinge 202(1) into the second portion 104 and a length (represented here as distance “D”) of the flexible hinge 202(1) in the second portion 104 changes as the bias is (partially) overcome as the first and second portions 102 and 104 are rotated through a range of angles.

Note that in this implementation, the flexible hinge 202(1) is closer to one surface of the first and second portions 102 and 104 than the opposing surface (e.g., the flexible hinge does not bisect the first and second portions). Thus, the amount of the intervening portion 410(1) exposed in the 90 degree orientation of Instance Two is different than the amount exposed in the 270 degree orientation of Instance Four. In other implementations, the flexible hinge could bisect the first and second portions. As a result, the 90 and 270 degree orientation could be more similar than those shown here.

FIG. 8 shows how magnets 204(1) and 204(2) in the first and second portions 102 and 104 respectively can bias the device 100 into specific orientations and/or bias the device to maintain those specific orientations.

Instance One shows the device portions 102 and 104 in a closed configuration (e.g., angle α is zero degrees) where the portions overlay one another. Magnets 204(1) and 204(2) interact (e.g., attract one another) to create a bias toward this closed configuration. For instance, the North (N) pole of a side surface of magnet 204(2) is positioned proximate to the South (S) pole of a side surface of magnet 204(1) and the North Pole of magnet 204(1) is positioned proximate to the South Pole of magnet 204(2). The attraction between the magnets creates a force holding the first and second portions in this closed configuration. A user can apply a greater force to overcome the magnetic force and open the device.

Instance Two shows the device opened to about 130 degrees, which can be termed an intervening orientation (e.g., between closed and fully open). At this point magnetic attraction between the side surfaces of magnets 204(1) and 204(2) in the first and second portions 102 and 104 is diminishing while magnetic attraction between end surfaces of the magnets can create a force that biases the device to continue to open. Specifically, the attractive force between the North Pole of the end surface of magnet 204(1) and the South Pole of the end surface of magnet 204(2) is increasing. This attraction can bias the device into the open configuration of Instance Three.

Instance Three shows the attraction between magnets 204(1) and 204(2) biasing the device 100 toward this fully open orientation where the first and second portions 102 and 104 are juxtaposed and coplanar. Not only do the magnets function to bias the first and second portions toward the open orientation, the magnets function to maintain the device in this open orientation. The attractive force between the end surfaces of the magnets 204(1) and 204(2) can also cause the device portions to be pulled together until the device portions abut one another (discussed above relative to FIGS. 4 and 7). This configuration can create a combined single planar surface upon which a single GUI can be displayed across.

Instance Four shows where the user has applied a force to fold or close the device 100 so that the first and second portions 102 and 104 are now oriented at about 270 degrees. At this point, the attractive forces of the end surfaces of magnets 204(1) and 204(2) of the first and second portions 102 and 104 are decreasing and the attractive forces of the side surfaces of magnets 204(1) and 204(2) on each other is increasing. The attraction of the side surfaces of magnets 204(1) and 204(2) can bias the device toward the orientation of Instance Five.

Instance Five shows the device in a closed orientation (e.g., angle α equals 360 degrees). This orientation is identical to the orientation of Instance One except that the inward and outward facing surfaces are reversed. The attraction between magnets 204(1) and 204(2) biases the device to maintain this orientation (e.g., the device portions will not rotate away from one another unless acted upon by a force, such as the user rotating them apart).

From one perspective, FIG. 8 shows how magnets 204(1) and 204(2) can operate cooperatively to create forces that bias the device portions 102 and 104 toward specific orientations. Thus, from one perspective, magnets 204(1) and 204(2) can be thought of as a magnetic assembly 800 that is configured to bias the first and second portions to specific angular orientations or configurations.

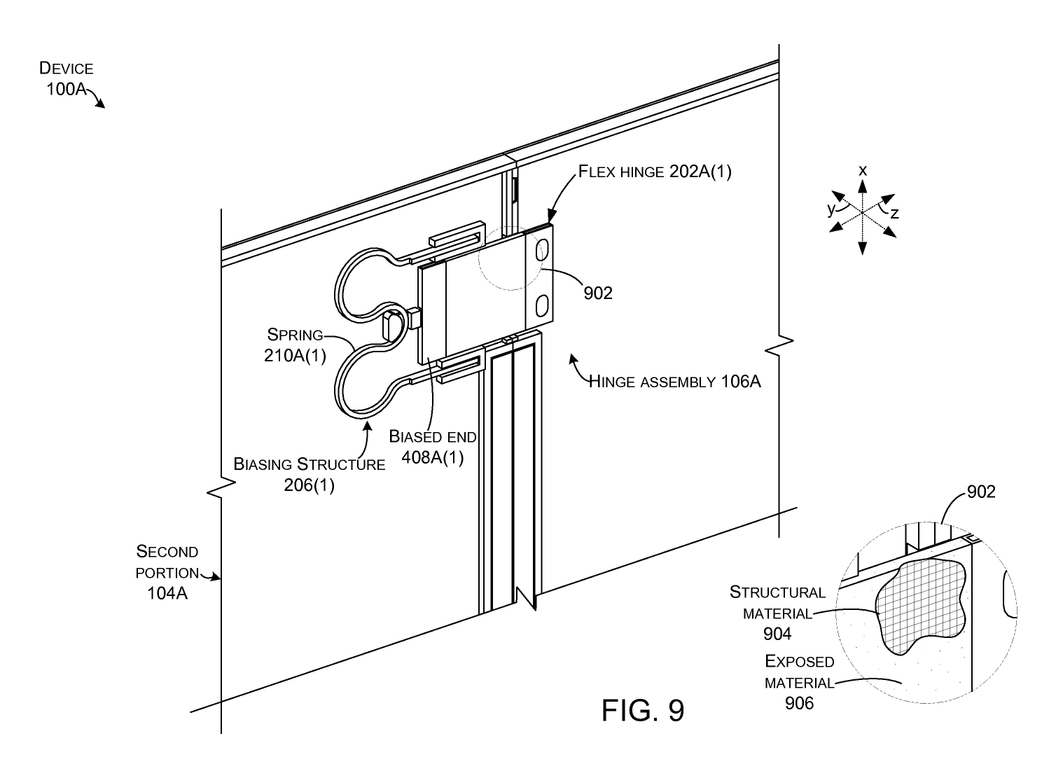

FIG. 9 shows another device 100A. This device includes a hinge assembly 106A where individual flexible hinges 202A(1) are biased by dedicated springs 210A(1) rather than the shared or common spring 210 of device 100 (See FIG. 2). Thus, the biasing structure 206A(1) is manifest as spring 210A(1) that is connected to the biased end 408A(1) of flexible hinge 202A(1). In this case, the ends of the spring 210A(1) are connected to the second portion 104A and the center of the spring is connected to the biased end 408A(1) of the flexible hinge. Other spring types can be used in alternative implementations.

FIG. 9 also shows one configuration of a material construction of the flexible hinge 202A(1) in enlarged view 902. In this example, the flexible hinge is manifest as an underlying matrix of structural material 904, such as mesh. For instance, the mesh could be formed from metal or an organic material, such as polyester, nylon, etc. The mesh can be overlaid with an exposed material 906, such as a flexible polymer, which can create a smooth texture and/or appearance of the flexible hinge. The size of the metal mesh can be selected to contribute to a radio frequency Faraday cage around the flexible circuit (208, FIG. 5). Other flexible hinges can be made from a single component and/or from other components from those described here. For instance, multiple different layers of components can be laminated or otherwise secured together to create the flexible hinge. Alternatively, the flexible hinge could be manifest as a single component material.

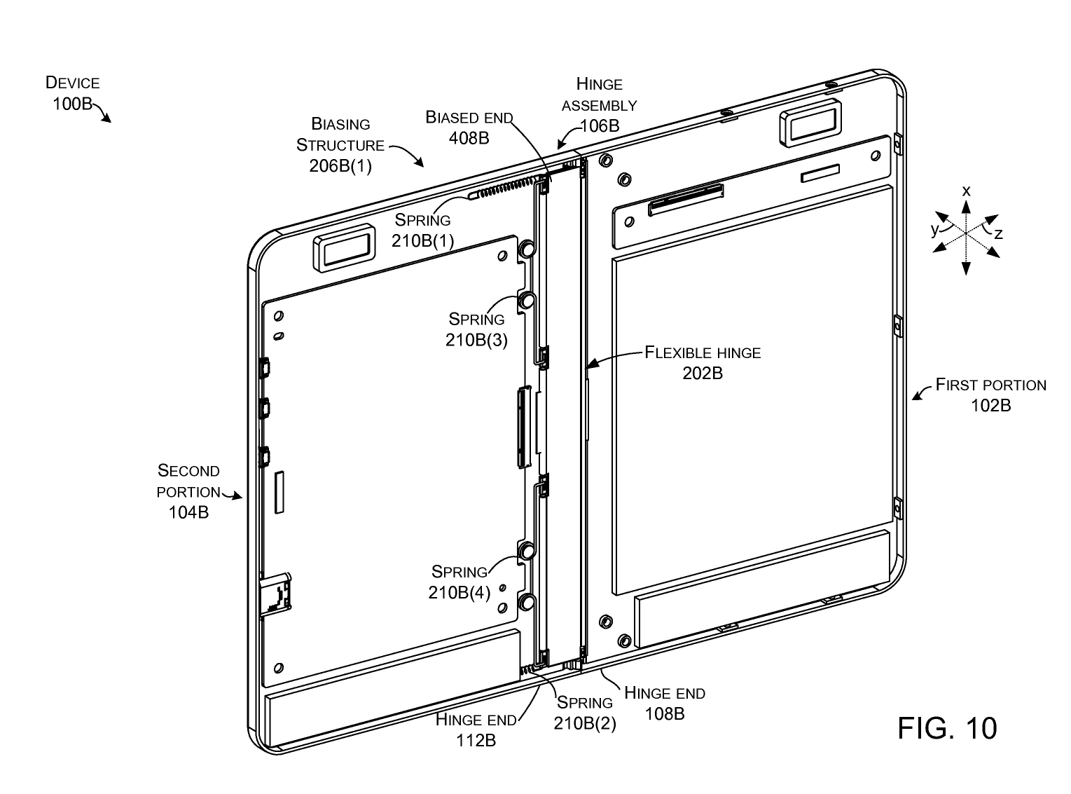

FIG. 10 shows another example hinge assembly 106B on device 100B. In this case, hinge assembly 106B includes a single flexible hinge 202B. The flexible hinge 202B extends along a majority of the hinge ends 108B and 112B of the first and second portions 102B and 104B. In this case, the biasing structure 206B(1) includes multiple springs 210B that bias the flexible hinge 202B. For example, a pair of distal springs 210B(1) and 210B(2) are positioned at the top and bottom of the flexible hinge 202B. A pair of central springs 210B(3) and 210B(4) are interposed between the distal springs. The springs 210B serve to collectively bias the biased end 408B of the flexible hinge.

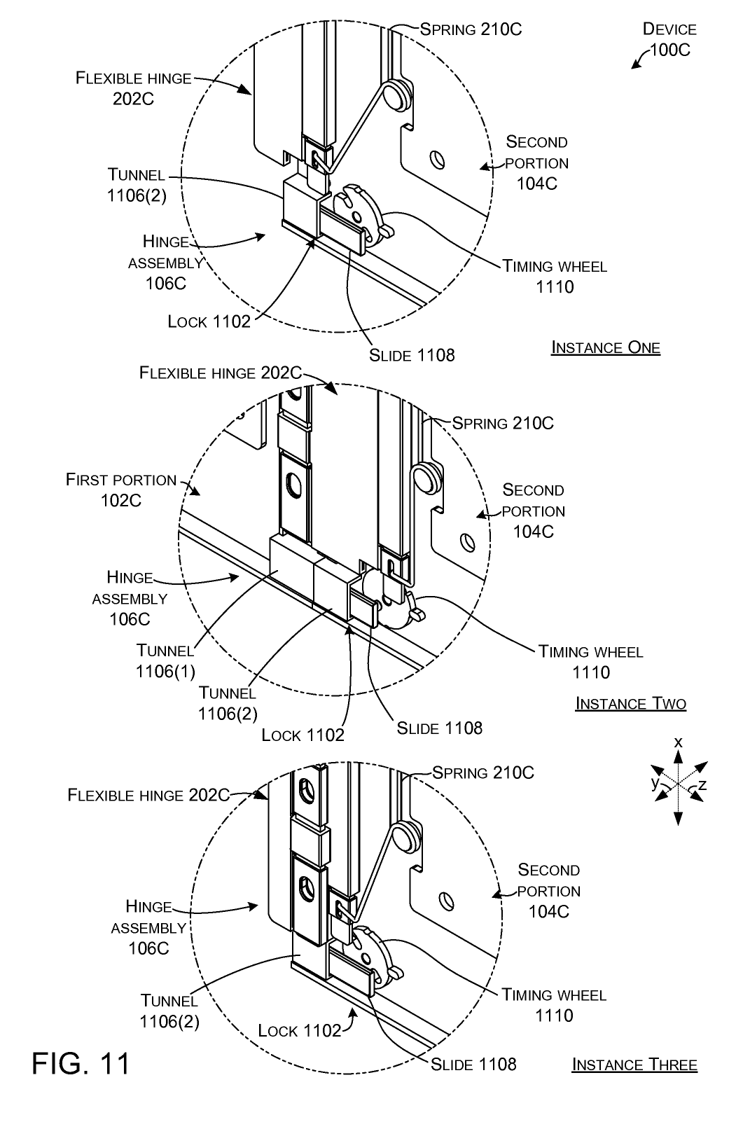

FIG. 11 shows another example hinge assembly 106C on device 100C. The hinge assembly rotatably connects first and second portions 102C and 104C. Instance One shows the first and second portions at zero degrees, Instance Two show the first and second portions at 180 degrees, and Instance Three shows the first and second portions at 360 degrees. Note that the first portion is only visible in Instance Two. In Instance One the first portion 102C is folded behind the second portion 104C. In Instance Three, the first portion would be folded in front of the second portion (e.g., toward the viewer) but is removed so that underlying portions of the hinge assembly 106C can be visualized.

Hinge assembly 106C includes a lock 1102 that is manifest as a first tunnel structure (e.g., first tunnel) 1106(1), a second tunnel structure (e.g., second tunnel) 1106(2), a slide 1108, and a timing wheel 1110. The first tunnel 1106(1) is positioned on the first portion 102B and the second tunnel 1106(2) on the second portion 104C. The slide 1108 is extendably secured into the second tunnel 1106(2). As evidenced by comparing Instance One to Instance Two, the slide 1108 can be extended into the first tunnel 1106(1) in the 180 degree position to lock the first and second portions at this orientation. Operation of the slide 1108 can be controlled by the timing wheel 1110. As the first and second portions approach 180 degrees, the flexible hinge 202C can be drawn into the second portion 104C by spring 210C. The flexible hinge 202C can engage and rotate the timing wheel 1110 and turn the timing wheel in a clock-wise direction. The timing wheel 1110 is secured to the slide 1108 such that rotation of the timing wheel extends the slide 1108 into tunnel 1106(1) of the first portion 102C, thereby locking the first and second portions 102C and 104C in this orientation.

Further rotation of the first and second portions 102C and 104C (e.g., from Instance Two to Instance Three) causes the flexible hinge 202C to be withdrawn from the second portion 104C (e.g., to move in the negative z reference direction). This movement disengages the flexible hinge 202C from the timing wheel 1110. The timing wheel rotates in the counter clock-wise direction and the slide 1108 is retracted from tunnel 1106(1), which allows rotation of the first portion relative to the second portion. Other implementations can employ other lock types.

The present hinge assembly concepts can be utilized with any type of device, such as, but not limited to, notebook computers, smart phones, wearable smart devices, tablets, and/or other types of existing, developing, and/or yet to be developed devices.

### EXAMPLE METHODS

Various methods of manufacture, assembly, and use for hinge assemblies and devices are contemplated beyond those shown above relative to FIGS. 1-11.

### ADDITIONAL EXAMPLES

Various example hinge assemblies and device are described above. Additional examples are described below. One example can include a device comprising a first portion and a second portion and a hinge assembly secured to a hinge end of the first portion and a hinge end of the second portion. The hinge assembly rotatably secures the first and second portions and is comprised of a flexible hinge coupled to the first and second portions and a biasing structure that biases the flexible hinge into the second portion. A length of the flexible hinge in the second portion changes as the first and second portions are rotated through a range of angles.

Another example can include any combination of the above and/or below examples where the device further comprises a flexible circuit extending between the first and second portions and electrically coupling the first and second portions.

Another example can include any combination of the above and/or below examples where the flexible circuit is coextensive with the flexible hinge.

Another example can include any combination of the above and/or below examples where the flexible hinge contributes to a Faraday Cage around the flexible circuit.

Another example can include any combination of the above and/or below examples where the flexible hinge comprises a single flexible hinge or wherein the flexible hinge comprises multiple hinges.

Another example can include any combination of the above and/or below examples where the flexible hinge comprises first and second hinges.

Another example can include any combination of the above and/or below examples where the biasing structure comprises first and second biasing structures, and where the first biasing structure acts on the first flexible hinge and the second biasing structure acts on the second flexible hinge.

Another example can include any combination of the above and/or below examples where the first and second flexible hinges are both biased by the biasing structure.

Another example can include any combination of the above and/or below examples where the biasing structure comprises a spring that is positioned between the first and second flexible hinges and where a first end of the spring is connected to the first flexible hinge and a second end of the spring is connected to the second flexible hinge.

Another example can include any combination of the above and/or below examples where the first end of the spring is directly connected to the first flexible hinge and the second end of the spring is directly connected to the second flexible hinge.

Another example can include any combination of the above and/or below examples where the first end of the spring is connected to the first flexible hinge by a first elongate material and the second end of the spring is connected to the second flexible hinge by a second elongate material.

Another example can include any combination of the above and/or below examples where the first elongate material follows a circuitous path from the first end of the spring to the first flexible hinge and where the second elongate material follows another circuitous path from the second end of the spring to the second flexible hinge.

Another example can include any combination of the above and/or below examples where the first and second elongate material comprise wire or cable.

Another example can include any combination of the above and/or below examples where the device further comprises first magnets positioned in the first portion and second magnets positioned in the second portion and wherein the first and second magnets predispose the first and second portions toward specific angular orientations.

Another example can include any combination of the above and/or below examples where the specific angular orientations comprise 0 degrees, 180 degrees, and 360 degrees.

Another example can include a device comprising a first portion having a major surface and a second portion having another major surface. The device also comprises a flexible hinge securing the first and second portions through a range of angular orientations. At a closed angular orientation the first and second portions are adjacent to one another and the major surface overlays the another major surface. At a fully open angular orientation the major surface and the another major surface abut one another and are coplanar and a portion of the flexible hinge is biased into the second portion.

Another example can include any combination of the above and/or below examples where the first and second portions further include magnets that are oriented to bias the first and second portions to the closed angular orientation and the fully open angular orientation.

Another example can include any combination of the above and/or below examples where the first major surface and the second major surface comprise displays.

Another example can include any combination of the above and/or below examples where the device further includes a processor that generates a single graphical user interface for collective presentation across the displays when the device is in the fully open angular orientation and separate graphical user interfaces when the device is in other orientations.

Another example includes a device comprising a first portion and a second portion and a hinge assembly rotatably securing the first portion and the second portion with a flexible hinge that is biased into the second portion such that a length of the flexible hinge exposed between the first and second portions changes as the first and second portions are rotated through a range of angular orientations.

Another example includes a hinge assembly comprising a flexible hinge having a first end configured to be fixedly secured to a first surface and a second end configured to be slideably secured to a second surface to rotatably secure the first and second surfaces. The hinge assembly further comprises a flexible circuit extending between the first end and the second end and configured to electrically couple the first and second surfaces, the flexible hinge being at least partially co-extensive with the flexible circuit, and where at least a portion of the flexible circuit is contained within the flexible hinge.

Another example can include any combination of the above and/or below examples where the flexible hinge comprises a mesh or wherein the flexible hinge comprises a solid material.

Another example can include any combination of the above and/or below examples where the flexible hinge comprises a polymer coated mesh.

Another example can include any combination of the above and/or below examples where the hinge assembly further comprises the first surface manifest on a first device portion and the second surface manifest on a second device portion, and where the flexible hinge is resiliently biased to pull a length of the flexible hinge into the second portion when the first and second portions are coplanar in an open configuration. The resilient bias can be overcome to withdraw some of the length when the first and second portions are folded over one another in a closed configuration.

Another example can include any combination of the above and/or below examples where the flexible hinge contributes to a Faraday Cage shielding the flexible circuit.

### CONCLUSION

Although techniques, methods, devices, systems, etc., pertaining to hinge assemblies are described in language specific to structural features and/or methodological acts, it is to be understood that the subject matter defined in the appended claims is not limited to the specific features or acts described. Rather, the specific features and acts are disclosed as example forms of implementing the claimed methods, devices, systems, etc.

1. A device, comprising:
a first portion and a second portion; and,
a hinge assembly secured to a hinge end of the first portion and a hinge end of the second portion to rotatably secure the first and second portions, the hinge assembly comprising:
a flexible hinge coupled to the first and second portions; and
a biasing structure that biases the flexible hinge into the second portion, wherein a length of the flexible hinge in the second portion changes as the first and second portions are rotated through a range of angles.

2. The device of claim 1, further comprising a flexible circuit extending between the first and second portions and electrically coupling the first and second portions.

3. The device of claim 2, wherein the flexible circuit is coextensive with the flexible hinge.

4. The device of claim 3, wherein the flexible hinge contributes to a Faraday Cage around the flexible circuit.

5. The device of claim 1, wherein the flexible hinge comprises a single flexible hinge or wherein the flexible hinge comprises multiple flexible hinges.

6. The device of claim 1, wherein the flexible hinge comprises first and second flexible hinges.

7. The device of claim 6, wherein the biasing structure comprises first and second biasing structures, and wherein the first biasing structure acts on the first flexible hinge and the second biasing structure acts on the second flexible hinge.

8. The device of claim 6, wherein the first and second flexible hinges are both biased by the biasing structure.

9. The device of claim 8, wherein the biasing structure comprises a spring that is positioned between the first and second flexible hinges and wherein a first end of the spring is connected to the first flexible hinge and a second end of the spring is connected to the second flexible hinge.

10. The device of claim 9, wherein the first end of the spring is directly connected to the first flexible hinge and the second end of the spring is directly connected to the second flexible hinge.

11. The device of claim 9, wherein the first end of the spring is connected to the first flexible hinge by a first elongate material and the second end of the spring is connected to the second flexible hinge by a second elongate material.

12. The device of claim 11, wherein the first elongate material follows a circuitous path from the first end of the spring to the first flexible hinge and wherein the second elongate material follows another circuitous path from the second end of the spring to the second flexible hinge.

13. The device of claim 11, wherein the first and second elongate material comprise wire or cable.

14. The device of claim 1, further comprising first magnets positioned in the first portion and second magnets positioned in the second portion and wherein the first and second magnets predispose the first and second portions toward specific angular orientations.

15. The device of claim 14, wherein the specific angular orientations comprise 0 degrees, 180 degrees, and 360 degrees.

16. A device, comprising:
a first portion having a major surface and a second portion having another major surface; and,
a flexible hinge securing the first and second portions through a range of angular orientations, wherein at a closed angular orientation the first and second portions are adjacent to one another and the major surface overlays the another major surface and at a fully open angular orientation the major surface and the another major surface abut one another and are coplanar and a portion of the flexible hinge is biased into the second portion.

17. The device of claim 16, wherein the first and second portions further include magnets that are oriented to bias the first and second portions to the closed angular orientation and the fully open angular orientation.

18. The device of claim 16, wherein the first major surface and the second major surface comprise displays.

19. The device of claim 18, wherein the device further includes a processor that generates a single graphical user interface for collective presentation across the displays when the device is in the fully open angular orientation and separate graphical user interfaces when the device is in other orientations.

20. A device, comprising:
a first portion and a second portion; and,
a hinge assembly rotatably securing the first portion and the second portion with a flexible hinge that is biased into the second portion such that a length of the flexible hinge exposed between the first and second portions changes as the first and second portions are rotated through a range of angular orientations.

21. A hinge assembly, comprising:
a flexible hinge having a first end configured to be fixedly secured to a first surface and a second end configured to be slideably secured to a second surface to rotatably secure the first and second surfaces;
a flexible circuit extending between the first end and the second end and configured to electrically couple the first and second surfaces; and,
the flexible hinge being at least partially co-extensive with the flexible circuit, and wherein at least a portion of the flexible circuit is contained within the flexible hinge.

22. The hinge assembly of claim 21, wherein the flexible hinge comprises a mesh or wherein the flexible hinge comprises a solid material.

23. The hinge assembly of claim 21, wherein the flexible hinge comprises a polymer coated mesh.

24. The hinge assembly of claim 21, further comprising the first surface manifest on a first device portion and the second surface manifest on a second device portion, and wherein the flexible hinge is resiliently biased to pull a length of the flexible hinge into the second device portion when the first and second device portions are coplanar in an open configuration and wherein the resilient bias is overcome to withdraw some of the length when the first and second device portions are folded over one another in a closed configuration.

25. The hinge assembly of claim 21, wherein the flexible hinge contributes to a Faraday Cage shielding the flexible circuit.
